(19) United States
(12) Patent Application Publication
(10) Pub. No.: US 2025/0286364 A1
(43) Pub. Date: Sep. 11, 2025

(54) OVERVOLTAGE PROTECTION CIRCUIT AND SEMICONDUCTOR DEVICE

(71) Applicant: FUJI ELECTRIC CO., LTD., Kawasaki-shi (JP)

(72) Inventor: Yuta SHIBASAKI, Matsumoto-city (JP)

(73) Assignee: FUJI ELECTRIC CO., LTD., Kawasaki-shi (JP)

(21) Appl. No.: 19/041,249

(22) Filed: Jan. 30, 2025

(30) Foreign Application Priority Data
Mar. 11, 2024 (JP) 2024-036943

(51) Int. Cl. H02H 9/04; H10D 89/60

(52) U.S. Cl. CPC H02H 9/04; H10D 89/611; H10D 89/711

(57) ABSTRACT

An overvoltage protection circuit includes an overvoltage detection circuit, a resistance value selection circuit, and a clamp circuit. The clamp circuit includes a resistor unit providing a plurality of resistance values and a transistor. The overvoltage detection circuit detects whether a voltage applied to a power supply terminal of the overvoltage protection circuit is in an overvoltage state. The resistance value selection circuit selects a resistance value from the plurality of resistance values, depending on the overvoltage state. The transistor is turned on by a drive current that flows based on the selected resistance value, forms a current path between the power supply terminal and a ground terminal of the overvoltage protection circuit, and draws a current from the power supply terminal, so as to clamp the voltage.

### CROSS-REFERENCE TO RELATED APPLICATION

This application is based upon and claims the benefit of priority of the prior Japanese Patent Application No. 2024-036943, filed on Mar. 11, 2024, the entire contents of which are incorporated herein by reference.

### BACKGROUND OF THE INVENTION

### 1. Field of the Invention

The embodiments discussed herein relate to an overvoltage protection circuit and a semiconductor device.

### 2. Background of the Related Art

A semiconductor device such as an intelligent power module (IPM) includes semiconductor chips including power semiconductor elements, and a control IC driving these semiconductors chip is provided with an overvoltage protection function for protecting internal circuits from an overvoltage.

As a related technique, for example, there has been proposed a technique in which an electrostatic protection circuit sets the bias voltage of a transistor, and a switch circuit switches the bias voltage based on a power supply state based on a surge voltage (Japanese Laid-open Patent Publication No. 2013-098260). In addition, there has been proposed a technique in which, when the voltage at an internal node is detected to be an electrostatic discharge, the voltage at the internal node is clamped by allowing the current of the electrostatic discharge to flow from the internal node to a ground node (Japanese Laid-open Patent Publication No. 2020-155586). There has also been proposed a technique in which an electrostatic discharge protection circuit switches the value of a pull-down resistor connected to a power transistor based on the operation or non-operation of a protection target circuit (Japanese Laid-open Patent Publication No. 2022-180756).

### SUMMARY OF THE INVENTION

In one aspects of the embodiments, there is provided an overvoltage protection circuit, including: a power supply terminal having a voltage applied t thereto; a ground terminal; an overvoltage detection circuit configured to detect whether the voltage applied to the power supply terminal is in an overvoltage state; a resistance value selection circuit configured to select a resistance value from a plurality of resistance values, depending on the overvoltage state; and a clamp circuit which includes a resistor unit providing the plurality of resistance values, and a transistor configured to be turned on by a drive current thereof that flows based on the selected resistance value, to thereby form a current path between the power supply terminal and the ground terminal to draw a current from the power supply terminal, so as to clamp the voltage.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 illustrates an example of an overvoltage protection circuit;

FIG. 2 illustrates an example of a configuration of an overvoltage protection circuit according to a reference example;

FIG. 3 illustrates an example of a configuration of an overvoltage protection circuit according to the present embodiment;

FIG. 4 illustrates an example of a resistor unit;

FIG. 5 illustrates an example of a first operation executed at application of an overvoltage to the overvoltage protection circuit;

FIG. 6 illustrates an example of a second operation executed at application of an overvoltage to the overvoltage protection circuit;

FIG. 7 illustrates examples of the waveforms of voltages clamped at overvoltage application;

FIG. 8 illustrates an example of a first configuration of the overvoltage protection circuit;

FIG. 9 illustrates an example of a second configuration of the overvoltage protection circuit;

FIG. 10 illustrates an example of a configuration of a semiconductor system; and

FIG. 11 illustrates an example of a circuit configuration of a drive circuit in a semiconductor device.

### DETAILED DESCRIPTION OF THE INVENTION

Hereinafter, the present embodiment will be described with reference to the accompanying drawings. In the present description and drawings, elements having substantially the same configuration will be denoted by the same reference characters, and redundant descriptions thereof will be omitted as appropriate.

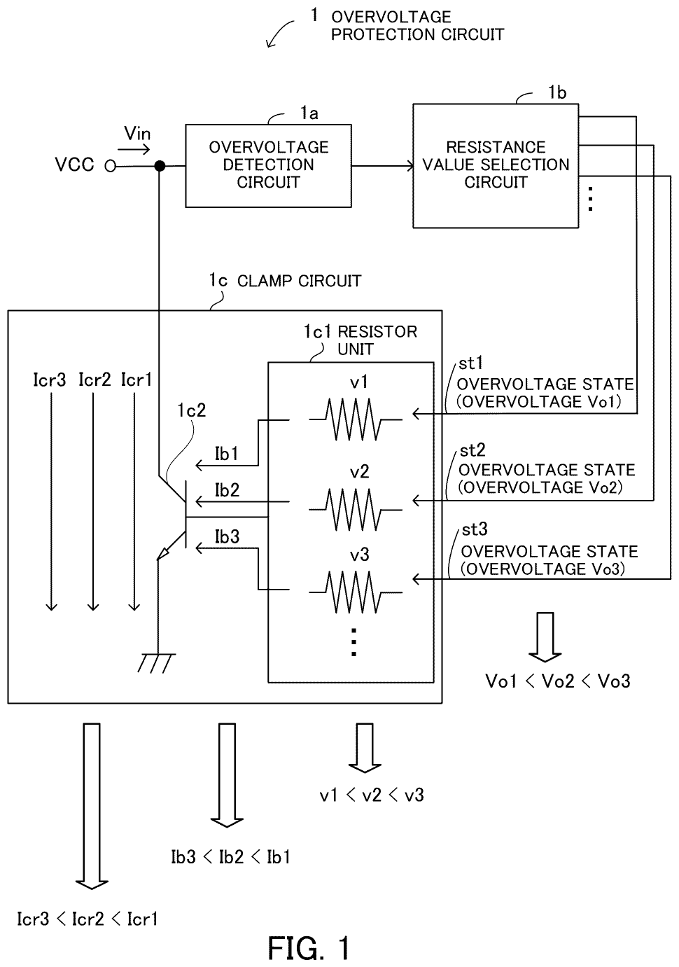

FIG. 1 illustrates an example of an overvoltage protection circuit. An overvoltage protection circuit 1 includes an overvoltage detection circuit 1a, a resistance value selection circuit 1b, and a clamp circuit 1c. The clamp circuit 1c includes a resistor unit 1c1 having a plurality of resistance values v1, v2, v3, and so on and a transistor 1c2. The clamp circuit 1c clamps a voltage Vin to a predetermined voltage.

The overvoltage detection circuit 1a detects whether the voltage Vin applied to a power supply terminal VCC is in an overvoltage state. The resistance value selection circuit 1b selects a predetermined resistance value from the plurality of resistance values v1, v2, v3, and so on in the resistor unit 1c1, depending on the overvoltage state.

For example, if the overvoltage detection circuit 1a detects that the voltage Vin indicates an overvoltage state st1 corresponding to an overvoltage Vo1, the resistance value selection circuit 1b selects the resistance value v1 in the resistor unit 1c1. If overvoltage detection circuit 1a detects that the voltage Vin indicates an overvoltage state st2 corresponding to an overvoltage Vo2 (>Vo1), the resistance value selection circuit 1b selects the resistance value v2 (>v1) in the resistor unit 1c1. If the overvoltage detection circuit 1a detects that the voltage Vin indicates an overvoltage state st3 corresponding to an overvoltage Vo3 (>Vo2), the resistance value selection circuit 1b selects the resistance value v3 (>v2) in the resistor unit 1c1.

The transistor 1c2 is turned on by a drive current that flows based on the predetermined resistance value selected by the resistance value selection circuit 1b. For example, in the overvoltage state st1, the transistor 1c2 is turned on by a drive current Ib1 that flows based on the resistance value v1. In the overvoltage state st2, the transistor 1c2 is turned on by a drive current Ib2 (<Ib1) that flows based on the resistance value v2. In the overvoltage state st3, the transistor 1c2 is turned on by a drive current Ib3 (<Ib2) that flows based on the resistance value v3.

Next, when the transistor 1c2 is turned on by the drive current, the transistor 1c2 forms a current path between the power supply terminal VCC and a ground terminal and draws a current from the power supply terminal VCC. For example, in the overvoltage state st1, the transistor 1c2 is turned on by the drive current Ib1 and draws a current (a collector current) Icr1 from the power supply terminal VCC. In the overvoltage state st2, the transistor 1c2 is turned on by the drive current Ib2 and draws a current Icr2 (<Icr1) from the power supply terminal VCC. In addition, in the overvoltage state st3, the transistor 1c2 is turned on by the drive current Ib3 and draws a current Icr3 (Icr2) from the power supply terminal VCC.

As described above, in the overvoltage protection circuit 1, a predetermined resistance value is selected from a plurality of resistance values, depending on overvoltage state, a transistor is turned on by a drive current that flows based on the predetermined resistance value selected, a current path is formed between a power supply terminal and a ground terminal, and a current is drawn from the power supply terminal.

In this way, it is possible to adaptively switch the operating resistance value that turns on the transistor depending on the magnitude of the overvoltage and to execute stepwise protection of the circuit elements from the overvoltage. That is, destruction of the circuit elements is prevented. For example, because an inflow of an inrush current associated with an overvoltage state, such as electro-static discharge (ESD), into the clamp circuit is prevented, thermal destruction of the circuit elements in the clamp circuit is prevented.

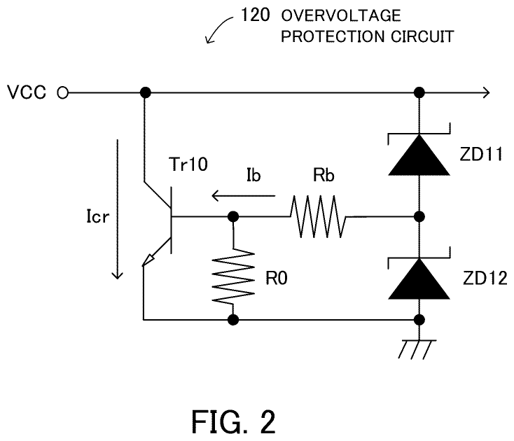

Next, an overvoltage protection circuit according to a reference example will be described with reference to FIG. 2. FIG. 2 illustrates an example of a configuration of an overvoltage protection circuit according to a reference example. An overvoltage protection circuit 120 according to the reference example includes Zener diodes ZD11 and ZD12, a base resistor Rb, a pull-down resistor R0, and a transistor Tr10. The transistor Tr10 is a bipolar transistor, and an NPN transistor is used in this example.

A power supply terminal VCC is connected to the collector of the transistor Tr10 and the cathode of the Zener diode ZD11. The anode of the Zener diode ZD11 is connected to one end of the base resistor Rb and the cathode of the Zener diode ZD12. The other end of the base resistor Rb is connected to the base of the transistor Tr10 and one end of the pull-down resistor R0. The emitter of the transistor Tr10 is connected to the other end of the pull-down resistor R0, the anode of the Zener diode ZD12, and a ground terminal (hereinafter referred to as GND, as appropriate).

The overvoltage protection circuit 120 is designed to clamp its voltage and to protect target circuits when an overvoltage is applied to the power supply terminal VCC. The overvoltage protection circuit 120 executes an overvoltage protection operation. When an overvoltage is applied to the power supply terminal VCC, the Zener diodes ZD11 and ZD12 undergo breakdown and allow a current to flow therethrough. When this happens, the voltage applied to the connection point of the anode of the Zener diode ZD11 and the cathode of the Zener diode ZD12 is applied to one end of the base resistor Rb, a base current Ib flows through the transistor Tr10, and the transistor Tr10 turns on.

When the transistor Tr10 turns on, a collector current Icr flows from the collector to the emitter. In addition, assuming that the direct-current (DC) amplification factor of the transistor Tr10 is h_{fe}, a current tens to hundreds of times greater than the base current Ib flows as collector current Icr, depending on the DC amplification factor h_{fe}.

As described above, when an overvoltage is applied to the power supply terminal VCC, the transistor Tr10 turns on, a current path is formed between the power supply terminal VCC and GND, and the overvoltage is drawn from the power supply terminal VCC as a current. This configuration enables clamping the voltage applied to the power supply terminal VCC to a predetermined voltage.

For example, if electric charges remain on the base of the transistor Tr10 immediately after the device is restarted, the transistor Tr10 could malfunction. The pull-down resistor R0 functions to draw these electric charges remaining on the base.

If, for example, a sharp and high-energy overvoltage such as ESD is applied to the power supply terminal VCC of the overvoltage protection circuit 120, an inrush current flows into the base of the transistor Tr10, and the transistor Tr10 could be destroyed. In this case, the entire overvoltage protection circuit 120 is destroyed by a short circuit.

One possible way to prevent the destruction due to an inflow of an inrush current into the transistor Tr10 is to increase the resistance value of the base resistor Rb. However, fixedly setting a large value as the resistance value of the base resistor Rb deteriorates the overvoltage protection function. In other words, the configuration of the overvoltage protection circuit 120 involves a trade-off. That is, increasing the resistance value of the base resistor achieves prevention of an inflow of an inrush current into the transistor but results in a deterioration in overvoltage protection function. Thus, it is difficult to execute accurate and reliable overvoltage protection control.

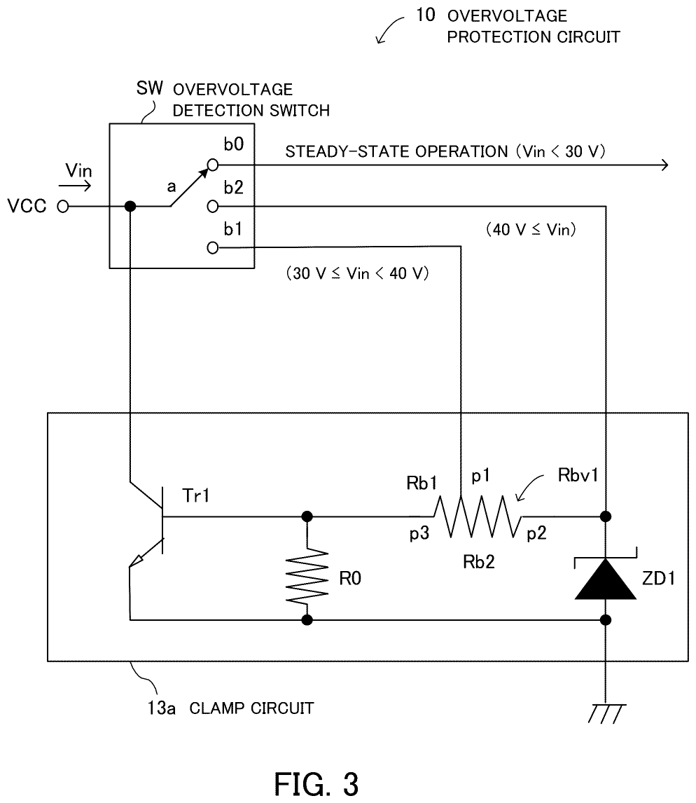

Next, an overvoltage protection circuit according to the present embodiment will be described in detail. FIG. 3 illustrates an example of a configuration of an overvoltage protection circuit according to the present embodiment. An overvoltage protection circuit 10 has the function of the overvoltage protection circuit 1 illustrated in FIG. 1, and includes an overvoltage detection switch SW and a clamp circuit 13a. The overvoltage detection switch SW schematically illustrates the functions of the overvoltage detection circuit 1a and the resistance value selection circuit 1b illustrated in FIG. 1.

The clamp circuit 13a includes a resistor unit Rbv1, a Zener diode ZD1, a pull-down resistor R0, and a transistor Tr1. The transistor Tr1 is a bipolar transistor, and an NPN transistor is used in this example.

In the following description, a case in which a voltage Vin applied to a power supply terminal VCC is less than 30 V (a first voltage) will be referred to as a voltage application state in a steady-state operation. In addition, in a case in which the voltage Vin applied to the power supply terminal VCC is 30 V or greater, the overvoltage protection circuit 10 determines that this voltage is an overvoltage. Specifically, the overvoltage protection circuit 10 executes overvoltage protection control in two steps, depending on the overvoltage state, one step being executed when the voltage Vin is 30 V or greater and is less than 40 V (a second voltage) (a first overvoltage state) and the other step being executed when the voltage Vin is 40 V or greater (a second overvoltage state).

The overvoltage detection switch SW includes a terminal a, and terminals b0, b1, and b2. One end of the terminal a is connected to the power supply terminal VCC and the collector of the transistor Tr1. The other end of the terminal a is connected to one of the terminals b0, b1, and b2, depending on the magnitude of the voltage Vin applied to the power supply terminal VCC.

The terminal b0 is connected to a downstream circuit (not illustrated) supplied with the voltage Vin applied to the power supply terminal VCC. The terminal b1 is connected to a point p1 (a predetermined point) of the resistor unit Rbv1. The terminal b2 is connected to a point p2 (a first end) of the resistor unit Rbv1 and the cathode of the Zener diode ZD1. A point p3 (a second end) of the resistor unit Rbv1 is connected to the base of the transistor Tr1 and one end of the pull-down resistor R0. The emitter of the transistor Tr1 is connected to the other end of the pull-down resistor R0, the anode of the Zener diode ZD1, and GND.

When the overvoltage detection switch SW detects that the voltage Vin applied to the power supply terminal VCC is less than 30 V, the overvoltage detection switch SW connects the terminal a to the terminal b0. The voltage Vin less than 30 V is not an overvoltage but a voltage applied in the steady-state operation, and therefore, no overvoltage protection control based on the clamp circuit 13a is executed.

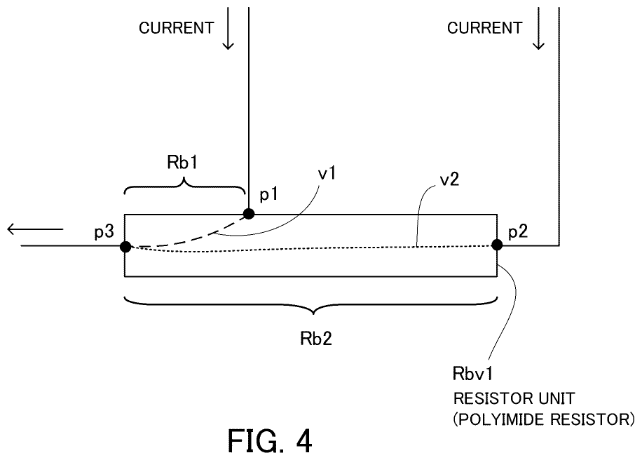

FIG. 4 illustrates an example of the resistor unit. The resistor unit Rbv1 is a resistor made of a polyimide material (the resistor unit Rbv1 will be hereinafter referred to as a polyimide resistor, as appropriate). The polyimide resistor has a resistance value R, which is calculated by the following equation (1) in which ρ represents the resistivity, L represents the length, and S represents the cross-sectional area.

R=ρ×L/S (1)

The resistance value of the polyimide resistor is made variable depending on the length L between the current input point and the current output point of the polyimide resistor and depending on the cross-sectional area S.

Thus, by adjusting the location of the current input point of the polyimide resistor, it is possible to freely change the polyimide resistor's resistance value between the current input point and the current output point. That is, a desired resistance value is obtained.

For example, the current output point of the polyimide resistor Rbv1 is set to the point p3 and the current input point of the polyimide resistor Rbv1 is set to the point p1 or p2. A resistance value v1 between the point p1 and the point p3 is determined based on the length between the point p1 and the point p3 and based on the cross-sectional area. In addition, a resistance value v2 between the point p2 and the point p3 is determined based on the length between the point p2 and the point p3 and based on the cross-sectional area.

Thus, by allowing a current to flow to the location of the point p1 of the polyimide resistor Rbv1, it is possible to set a resistor Rb1 having the resistance value v1 between the point p1 and the point p3. In addition, by allowing a current to flow to the location of the point p2 of the polyimide resistor Rbv1, it is possible to set a resistor Rb2 having the resistance value v2, which is greater than the resistance value v1, between the point p2 and the point p3.

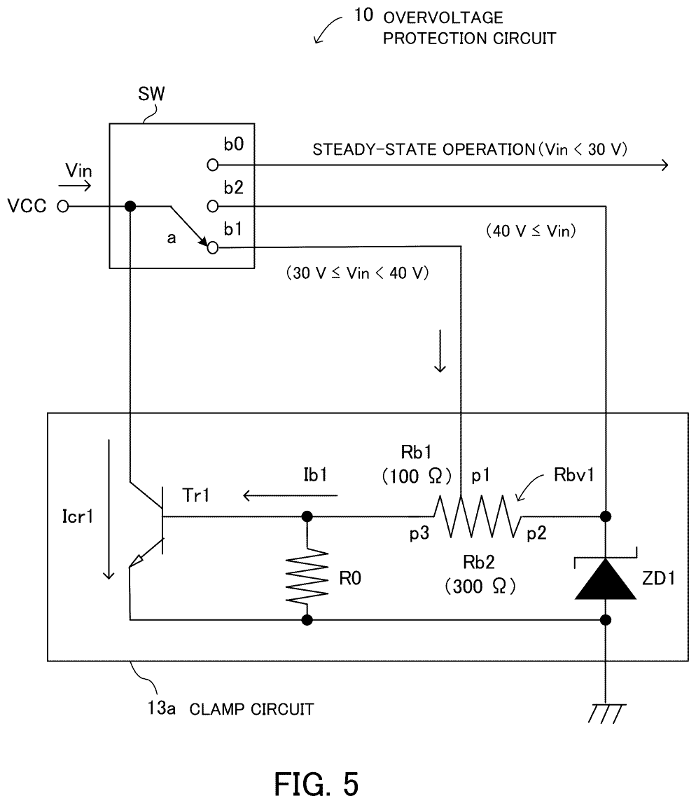

FIG. 5 illustrates an example of a first operation executed at application of an overvoltage to the overvoltage protection circuit. The following description assumes that the resistor Rb1 whose resistance value is 100 Ω is formed between the point p1 and the point p3 of the resistor unit Rbv1, and that the resistor Rb2 whose resistance value is 300 Ω is formed between the point p2 and the point p3 of the resistor unit Rbv1.

When the overvoltage detection switch SW detects that the voltage Vin applied to the power supply terminal VCC is 30 V or greater and is less than 40 V, the terminal a is connected to the terminal b1. Since the voltage Vin that is 30 V or greater and is less than 40 V is being applied to the power supply terminal VCC, overvoltage protection control based on the clamp circuit 13a is executed.

When such an overvoltage that is 30 V or greater and is less than 40 V is applied to the power supply terminal VCC, the Zener diode ZD1 undergoes breakdown and allows a current to flow therethrough via the resistor unit Rbv1. In addition, since the terminal a is connected to the terminal b1 and a current is input to the point p1 of the resistor unit Rbv1, the resistor Rb1 having a resistance value of 100 Ω (a first resistance value) is formed between the point p1 and the point p3.

In addition, because the voltage applied to the point p1 is applied to one end of the base resistor Rb1, a base current Ib1 (a first drive current) based on the base resistor Rb1 having 100 Ω flows through the transistor Tr1, and the transistor Tr1 turns on. When the transistor Tr1 turns on, a current path is formed between the power supply terminal VCC and GND, a collector current Icr1 flows from the collector to the emitter, and the collector current Icr1 (a first current) is drawn from the power supply terminal VCC.

As described above, when an overvoltage that is 30 V or greater and is less than 40 V is applied to the power supply terminal VCC, the base resistor Rb1 having 100 Ω as the operating resistance of the transistor Tr1 is selected. Next, the transistor Tr1 is turned on by the base current Ib1 based on the base resistor Rb1, and a current path is formed between the power supply terminal VCC and GND. That is, the overvoltage is drawn as a current from the power supply terminal VCC.

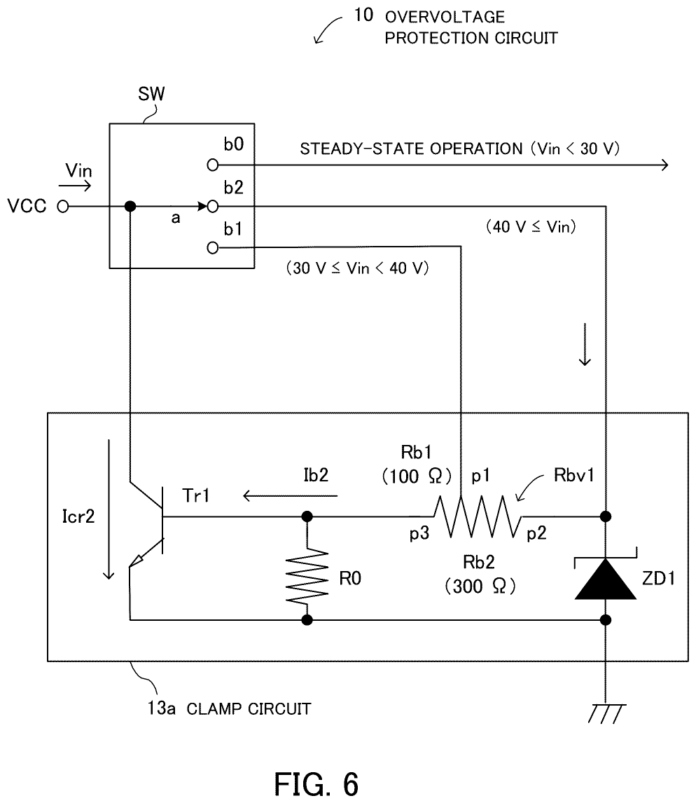

FIG. 6 illustrates an example of a second operation executed at application of an overvoltage to the overvoltage protection circuit. When the overvoltage detection switch SW detects that the voltage Vin applied to the power supply terminal VCC is 40 V or greater, the terminal a is connected to the terminal b2. Since the voltage Vin that is 40 V or greater is being applied to the power supply terminal VCC, overvoltage protection control based on the clamp circuit 13a is executed.

When an overvoltage that is 40 V or greater is applied to the power supply terminal VCC, the Zener diode ZD1 undergoes breakdown and allows a current to flow therethrough. In addition, since the terminal a is connected to the terminal b2 and a current is input to the point p2 of the resistor unit Rbv1, the resistor Rb2 having a resistance value of 300 Ω (a second resistance value) is formed between the point p2 and the point p3.

In addition, because the voltage applied to the point p2 is applied to one end of the base resistor Rb2, a base current Ib2 (a second drive current) (Ib2<Ib1) based on the base resistor Rb2 having 300 Ω flows through the transistor Tr1, and the transistor Tr1 turns on. When the transistor Tr1 turns on, a current path is formed between the power supply terminal VCC and GND, and a collector current Icr2 (<Icr1) flows from the collector to the emitter. That is, the collector current Icr2 (a second current) is drawn from the power supply terminal VCC.

As described above, when an overvoltage that is 40 V or greater is applied to the power supply terminal VCC, the base resistor Rb2 having 300 Ω as the operating resistance of the transistor Tr1 is selected. Next, the transistor Tr1 is turned on by the base current Ib2 based on the base resistor Rb2, and a current path is formed between the power supply terminal VCC and GND. As a result, the overvoltage is drawn as a current from the power supply terminal VCC.

The above description has been made based on an embodiment with reference to FIG. 1 and FIGS. 3 to 6 in which the overvoltage protection control is executed in two steps depending on the overvoltage state. However, the overvoltage protection control may be executed in three or more steps.

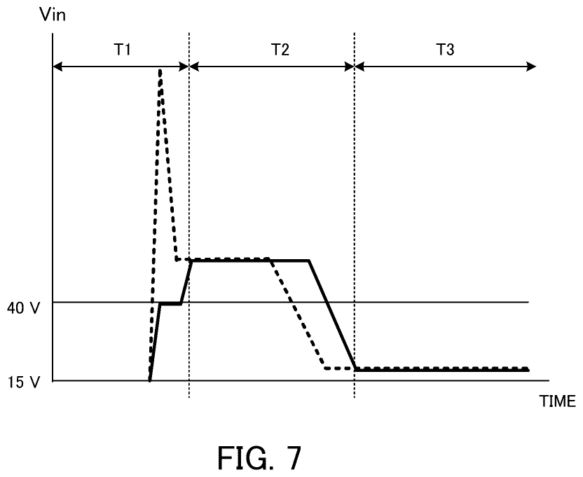

FIG. 7 illustrates examples of the waveforms of voltages clamped at overvoltage application. The vertical axis represents the voltage Vin applied to the power supply terminal VCC, and the horizontal axis represents time. The dotted waveform indicates the waveform of the voltage Vin clamped when an overvoltage is applied to the overvoltage protection circuit 120 according to the reference example. The solid waveform indicates the waveform of the voltage Vin clamped when an overvoltage is applied to the overvoltage protection circuit 10 according to the present embodiment.

In the case of the overvoltage protection circuit 120, to prevent destruction of circuit elements, the base resistor Rb is fixedly set to have a high resistance value. Thus, as illustrated by the dotted waveform, in a time period T1, the voltage Vin sharply rises. Next, in a time period T2, the overvoltage protection control is executed, and the overvoltage is brought in a DC state. Finally, in a time period T3, the voltage Vin is dropped back to the steady-operation state. However, if the base resistor Rb having a fixed high resistance value is used for the operating resistance of the transistor Tr10, the sharp level increase in ESD is not prevented in the time period T1. That is, deterioration in overvoltage protection function occurs. Therefore, even if destruction of the circuit elements inside the overvoltage protection circuit 120 is prevented, a circuit that needs to be originally protected from the overvoltage could be negatively affected.

Hereinafter, the operation of the solid waveform obtained from the overvoltage protection circuit 10 according to the present embodiment in the time periods T1, T2, and T3 will be descried.

[Time period T1] An overvoltage that is 30 V or greater is applied between the power supply terminal VCC and GND for a short time. In this case, the overvoltage protection circuit 10 operates as illustrated in FIG. 5. Thus, when an overvoltage that is 30 V or greater (for example, an overvoltage that is 30 V or greater for 10 nsec or longer) is applied to the overvoltage protection circuit 10, the overvoltage protection circuit 10 selects 100 Ω as the resistance value of the base resistor connected to the transistor Tr1, turns on the transistor Tr1 with the low resistance value of 100 Ω, and draws the overvoltage from the power supply terminal VCC as a current.

[Time period T2] If the overvoltage rises with the transistor Tr1 turned on with the base resistor having 100 Ω and the current drawn from the power supply terminal VCC (for example, 1 usec or longer), the transistor Tr1 could undergo thermal destruction. Thus, when the overvoltage protection circuit 10 is brought in an overvoltage state in which 40 V or greater is applied between the power supply terminal VCC and GND, the overvoltage protection circuit 10 shifts the operating state illustrated in FIG. 5 to the operating state illustrated in FIG. 6.

Thus, the overvoltage protection circuit 10 selects 300 Ω as the resistance value of the base resistor connected to the transistor Tr1, turns on the transistor Tr1 with the high resistance value of 300 Ω, and draws the overvoltage from the power supply terminal VCC as a current.

In this way, the overvoltage protection circuit 10 prevents thermal destruction of the transistor Tr1 while reducing the current drawn by the transistor Tr1 (the current amount drawn from the power supply terminal VCC is reduced). In addition, the increase in voltage Vin is prevented, and the voltage Vin is brought in a DC state (smoothed state).

[Time period T3] The protection operation of the overvoltage protection circuit 10 ends in this period. By drawing the overvoltage from the power supply terminal VCC as a current, the energy of the overvoltage (the energy of the surge voltage) is consumed. Thus, because the overvoltage state of the voltage Vin applied to the power supply terminal VCC is resolved, the overvoltage protection circuit 10 shifts to the operating state in FIG. 3 and is brought in a steady-operation state (for example, a steady-operation state at around 15 V).

As described above, the overvoltage protection circuit 10 is configured to switch the resistance value of the base resistor, which is the operating resistance of the transistor Tr1, depending on the magnitude of the overvoltage applied to the power supply terminal VCC. In the above-described example, when the overvoltage is 30 V or greater and is less than 40 V, the base resistor having 100 Ω is selected, and when the overvoltage is 40 V or greater, the base resistor having 300 Ω is selected.

Thus, when an overvoltage such as ESD of 40 V or greater is applied to the power supply terminal VCC, because the base resistor having the high resistance value is selected, an inrush current is not input to the base of the transistor Tr1, and thermal destruction of the transistor Tr1 due to an inrush current is prevented. In addition to preventing thermal destruction of the transistor Tr1 due to an inrush current, the overvoltage protection circuit 10 is able to clamp the overvoltage to a predetermined voltage by turning on the transistor Tr1 with the base current that flows through the base resistor having the high resistance value.

In addition, when an overvoltage that is 30 V or greater and that is less than 40 V is applied to the power supply terminal VCC, the base resistor having the low resistance value is selected. Thus, since the transistor Tr1 is turned on by the base current flowing through the base resistor having the low resistance value, it is possible to clamp the overvoltage to a predetermined voltage, without deteriorating the overvoltage detection function.

Thus, in the overvoltage state in which the voltage Vin is 40 V or greater, the overvoltage protection circuit 10 switches the resistance value of the base resistor from the low resistance value to the high resistance value, prevents input of an inrush current, and prevents destruction of the circuit elements. In the overvoltage state in which the voltage Vin is 30 V or greater and is less than 40 V, the overvoltage protection circuit 10 executes the overvoltage protection control by selecting the low resistance value as the resistance value of the base resistor. Therefore, deterioration of the overvoltage protection function is prevented.

As described above, since the overvoltage protection circuit 10 executes stepwise overvoltage protection by varying the resistance value of the base resistor, depending on the magnitude of the overvoltage, it is possible to achieve both prevention of destruction of the circuit elements and prevention of deterioration of the overvoltage protection function. That is, the above-described trade-off is mitigated, and accurate and reliable overvoltage protection control is realized.

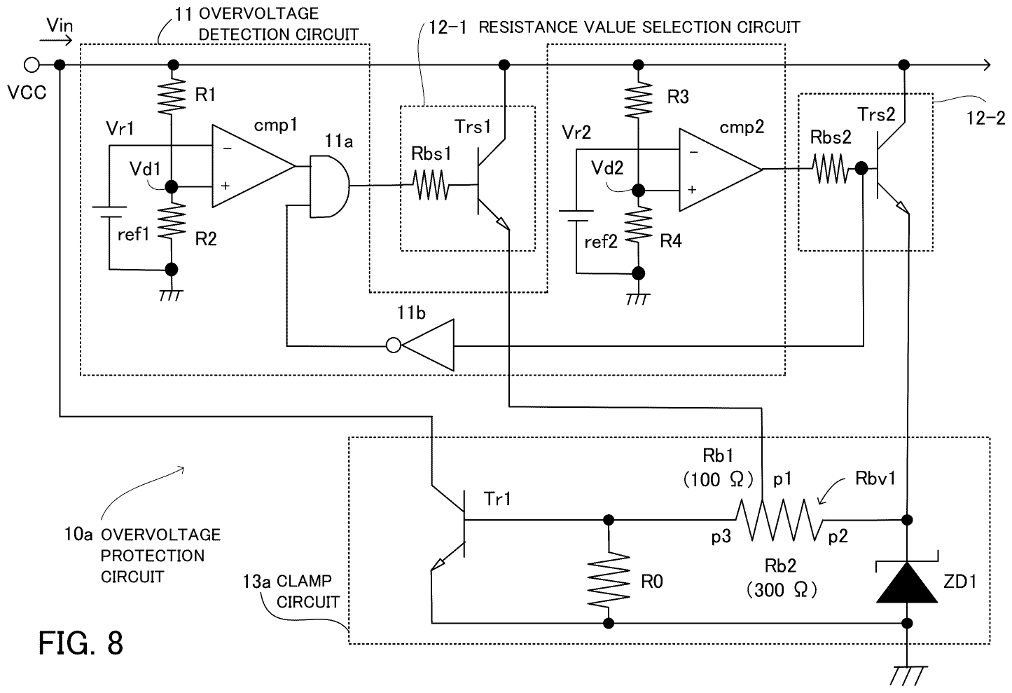

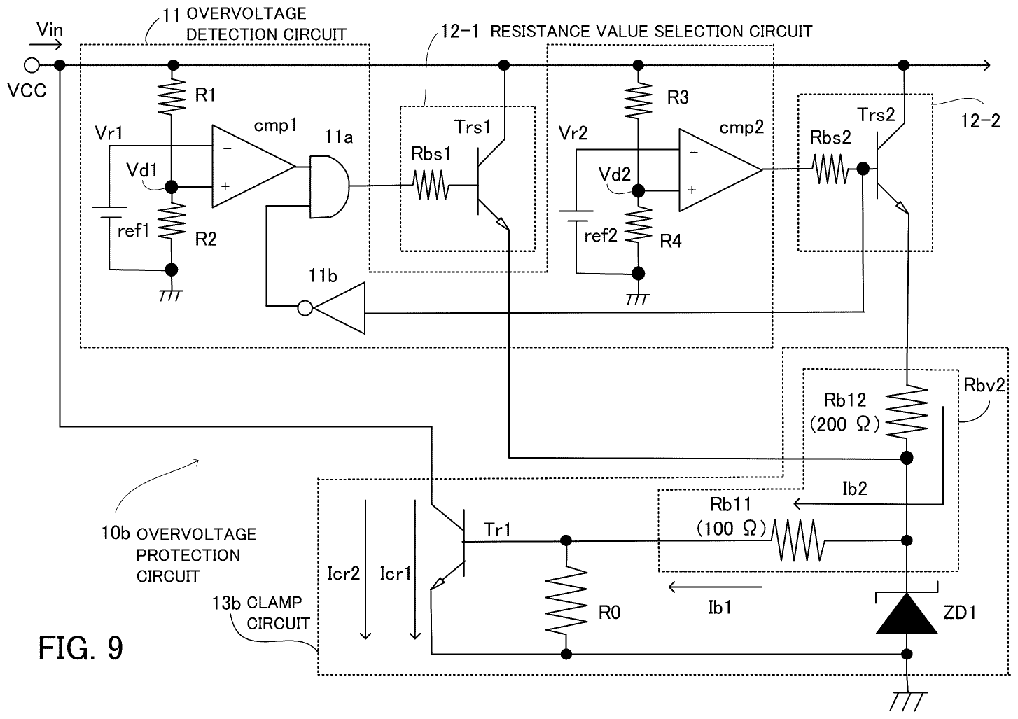

Next, configurations of the overvoltage protection circuit according to the present embodiment will be described with reference to FIGS. 8 and 9. FIG. 8 illustrates an example of a first configuration of the overvoltage protection circuit. An overvoltage protection circuit 10a includes an overvoltage detection circuit 11, a resistance value selection circuit 12-1 (a first resistance value selection circuit), a resistance value selection circuit 12-2 (a second resistance value selection circuit), and a clamp circuit 13a. The overvoltage detection circuit 11 and the resistance value selection circuits 12-1 and 12-2 realize the functions of the overvoltage detection switch SW illustrated in FIGS. 3, 5, and 6. Because the configuration of the clamp circuit 13a has already been described above, the description thereof will be omitted.

The overvoltage detection circuit 11 includes a comparator cmp1 (a first comparator), a comparator cmp2 (a second comparator), a resistor R1 (a first voltage divider resistor), a resistor R2 (a second voltage divider resistor), a resistor R3 (a third voltage divider resistor), a resistor R4 (a fourth voltage divider resistor), a reference voltage source ref1 (a first reference voltage source), a reference voltage source ref2 (a second reference voltage source), a 2-input 1-output AND element 11a, and an inverter element 11b.

The resistance value selection circuit 12-1 includes a transistor Trs1 (a first transistor) and a base resistor Rbs1 (a first base resistor), and the resistance value selection circuit 12-2 includes a transistor Trs2 (a second transistor) and a base resistor Rbs2 (a second base resistor). The transistors Trs1 and Trs2 are bipolar transistors, and NPN transistors are used in this example. A power supply terminal VCC is connected to the collector of a transistor Tr1, one end of the resistor R1, the collector of the transistor Trs1, one end of the resistor R3, and the collector of the transistor Trs2. The other end of the resistor R1 is connected to one end of the resistor R2 and the non-inverting input terminal (+) of the comparator cmp1. The inverting input terminal (−) of the comparator cmp1 is connected to the positive terminal of the reference voltage source ref1, and the negative terminal of the reference voltage source ref1 is connected to the other end of the resistor R2 and GND.

The output terminal of the comparator cmp1 is connected to one input terminal of the AND element 11a. The other input terminal of the AND element 11a is connected to the output terminal of the inverter element 11b. The output terminal of the AND element 11a is connected to one end of the base resistor Rbs1, and the other end of the base resistor Rbs1 is connected to the base of the transistor Trs1. The emitter of the transistor Trs1 is connected to a point p1 of a resistor unit Rbv1.

The other end of the resistor R3 is connected to one end of the resistor R4 and the non-inverting input terminal (+) of the comparator cmp2. The inverting input terminal (−) of the comparator cmp2 is connected to the positive terminal of the reference voltage source ref2, and the negative terminal of the reference voltage source ref2 is connected to the other end of the resistor R4 and GND.

The output terminal of the comparator cmp2 is connected to one end of the base resistor Rbs2, and the other end of the base resistor Rbs2 is connected to the input terminal of the inverter element 11b and the base of the transistor Trs2. The emitter of the transistor Trs2 is connected to a point p2 of the resistor unit Rbv1 and the cathode of a Zener diode ZD1.

In FIG. 8, a voltage Vin applied to the power supply terminal VCC is divided by the resistors R1 and R2, so as to obtain a voltage Vd1 (a first voltage). The voltage Vd1 is input to the non-inverting input terminal (+) of the comparator cmp1. In addition, the reference voltage source ref1 outputs a reference voltage Vr1 (a first reference voltage), and the reference voltage Vr1 is input to the inverting input terminal (−) of the comparator cmp1.

When the voltage Vin indicates 30 V or greater, the voltage Vd1 indicates the reference voltage Vr1 or greater, and an H level signal is output from the output terminal of the comparator cmp1. When the voltage Vin indicates less than 30 V, the voltage Vd1 indicates less than the reference voltage Vr1, and an L level signal is output from the output terminal of the comparator cmp1.

For example, when the value of the voltage Vin is halved by the resistors R1 and R2 and when the generated voltage Vd1 is input to the non-inverting input terminal (+) of the comparator cmp1, the reference voltage source ref1 is set to output 15 V (=30 V/2) as the reference voltage Vr1.

In addition, the voltage Vin applied to the power supply terminal VCC is divided by the resistors R3 and R4, so as to obtain a voltage Vd2 (a second voltage). The voltage Vd2 is input to the non-inverting input terminal (+) of the comparator cmp2. In addition, the reference voltage source ref2 outputs a reference voltage Vr2 (a second reference voltage), and the reference voltage Vr2 is input to the inverting input terminal (−) of the comparator cmp2. The reference voltage Vr2 is set to be a greater value than the reference voltage Vr1.

When the voltage Vin indicates 40 V or greater, the voltage Vd2 indicates the reference voltage Vr2 or greater, and an H level signal is output from the output terminal of the comparator cmp2. When the voltage Vin indicates less than 40 V, the voltage Vd2 indicates less than the reference voltage Vr2, and an L level signal is output from the output terminal of the comparator cmp2.

For example, when the value of the voltage Vin is halved by the resistors R3 and R4 and when the generated voltage Vd2 is input to the non-inverting input terminal (+) of the comparator cmp2, the reference voltage source ref2 is set to output 20 V (=40 V/2) as the reference voltage Vr2.

In FIG. 8, when the voltage Vin is less than 30 V, the comparator cmp1 outputs an L level signal, and the comparator cmp2 outputs an L level signal. Thus, because both the transistors Trs1 and Trs2 are off, the clamp circuit 13a does not operate.

In an overvoltage state in which the voltage Vin is 30 V or greater and is less than 40 V, the comparator cmp1 outputs an H level signal, and the comparator cmp2 outputs an L level signal. Thus, the transistor Trs2 turns off. However, the L level signal output from the comparator cmp2 is inverted to an H level signal by the inverter element 11b, and this H level signal is input to the other input terminal of the AND element 11a.

Thus, because an H level signal is output from the output terminal of the AND element 11a, the transistor Trs1 turns on. That is, because the transistor Trs1 turns on and the transistor Trs2 turns off, a current flows through the point p1 of the resistor unit Rbv1. That is, in the overvoltage state in which the voltage Vin is 30 V or greater and is less than 40 V, a resistance value of 100 Ω (a resistor Rb1) is selected.

In an overvoltage state in which the voltage Vin is 40 V or greater, the comparator cmp1 outputs an H level signal, and the comparator cmp2 outputs an H level signal. The transistor Trs2 is turned on by the output of the H level signal from the comparator cmp2. The H level signal output from the comparator cmp2 is inverted to an L level signal by the inverter element 11b, and this L level signal is input to the other input terminal of the AND element 11a.

Thus, because an L level signal is output from the output terminal of the AND element 11a, the transistor That is, because the transistor Trs1 turns Trs1 turns off off and the transistor Trs2 turns on, a current flows through the point p2 of the resistor unit Rbv1. That is, in the overvoltage state in which the voltage Vin is 40 V or greater, a resistance value of 300 Ω (a resistor Rb2) is selected.

FIG. 9 illustrates an example of a second configuration of the overvoltage protection circuit. An overvoltage protection circuit 10b includes an overvoltage detection circuit 11, resistance value selection circuits 12-1 and 12-2, and a clamp circuit 13b. The overvoltage detection circuit 11 and the resistance value selection circuits 12-1 and 12-2 are configured in the same way as illustrated in FIG. 8.

The clamp circuit 13b includes a resistor unit Rbv2, a Zener diode ZD1, a pull-down resistor R0, and a transistor Tr1. The clamp circuit 13b includes the resistor unit Rbv2, instead of the resistor unit Rbv1. The resistor unit Rbv2 includes a resistor Rb11 (a first resistor) having a resistance value of 100 Ω and a resistor Rb12 (a second resistor) having a resistance value of 200 Ω.

The cathode of the Zener diode ZD1 is connected to one end of the resistor Rb11, one end of the resistor Rb12, and the emitter of the transistor Trs1. The other end of the resistor Rb12 is connected to the emitter of the transistor Trs2. The other end of the resistor Rb11 is connected to one end of the pull-down resistor R0 and the base of the transistor Tr1. The emitter of the transistor Tr1 is connected to the other end of the pull-down resistor R0, the anode of the Zener diode ZD1, and GND. The collector of the transistor Tr1 is connected to the power supply terminal VCC.

In the overvoltage state in which the voltage Vin is 30 V or greater and is less than 40 V, as described above, the transistor Trs1 turns on, and the transistor Trs2 turns off. Thus, in the resistor unit Rbv2, the resistance value of 100 Ω (the resistor Rb11) is selected. As a result, a drive current Ib1 based on the resistor Rb11 is input to the base of the transistor Tr1, the transistor Tr1 turns on, and a current Icr1 is drawn from the power supply terminal VCC.

In the overvoltage state in which the voltage Vin is 40 V or greater, as described above, the transistor Trs1 turns off, and the transistor Trs2 turns on. Thus, in the resistor unit Rbv2, the resistance value of 300 Ω, which is the combined series resistance value of the resistor Rb11 having 100 Ω and the resistor Rb12 having 200 Ω, is selected. As a result, because a drive current Ib2 based on the combined series resistance value of the resistor Rb11 and the resistor Rb12 is input to the base of the transistor Tr1, the transistor Tr1 turns on, and a current Icr2 is drawn from the power supply terminal VCC.

As described above, the resistors Rb11 and Rb12 such as general-purpose carbon-film resistors may be used, without using a polyimide resistor. In this way, it is also possible to execute stepwise overvoltage protection control by varying the resistance value, depending on the magnitude of the overvoltage, as described above with reference to FIGS. 3, 5, and 6.

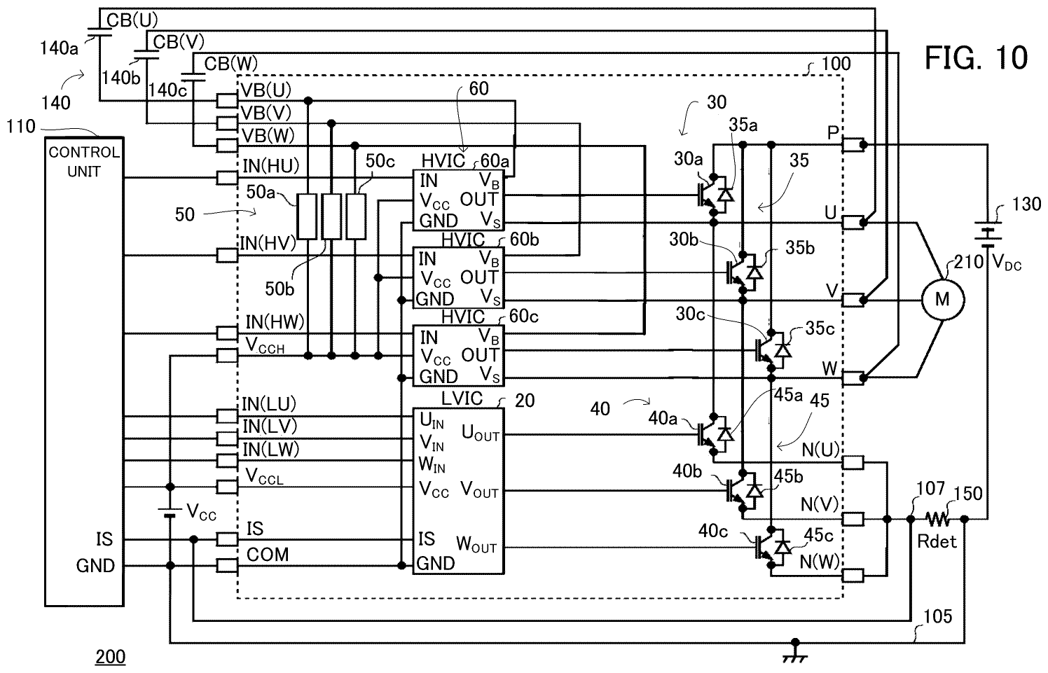

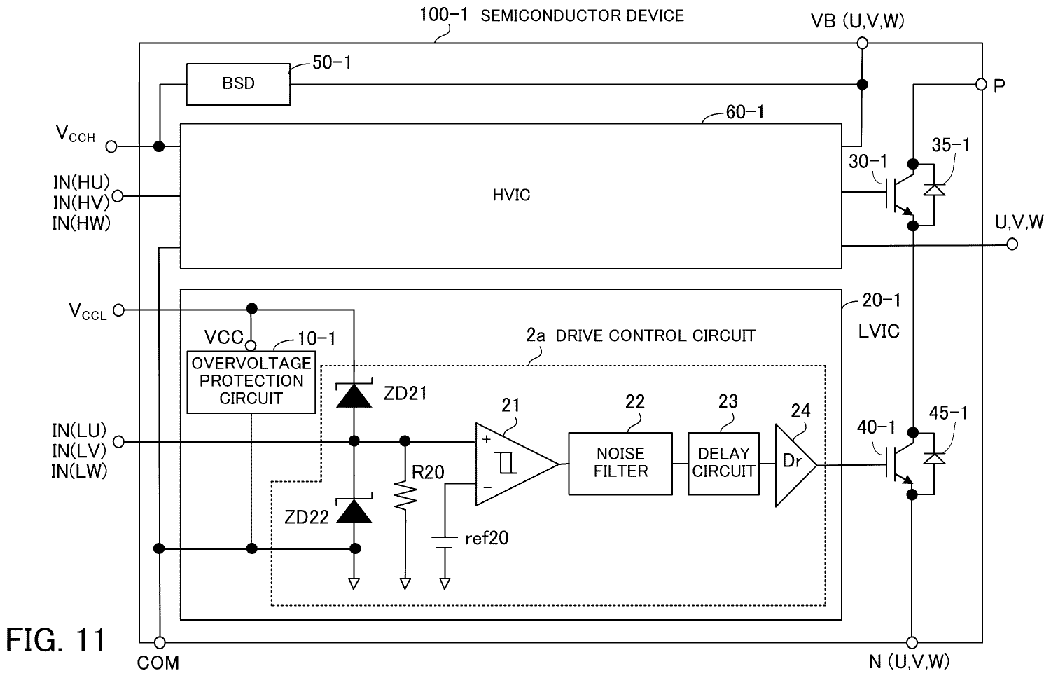

Next, a semiconductor device to which the overvoltage protection circuit 10 is applied will be described with reference to FIGS. 10 and 11. FIG. 10 illustrates an example of a configuration of a semiconductor system. A semiconductor system 200 is connected to a load 210, and switches on and off of the current supplied to the load 210. The semiconductor system 200 may function as a power conversion apparatus such as a motor drive inverter or a DC-DC converter. The semiconductor system 200 includes a semiconductor device 100, a control unit 110, a power supply 130, capacitors 140, and a current detection resistor 150.

The semiconductor device 100 is an IPM used for supplying power to the load 210, which consumes power. The semiconductor device 100 includes high side drive units 60 (60a, 60b, and 60c), a low side drive unit 20, high side switching elements 30 (30a, 30b, and 30c), high side diodes 35 (35a, 35b, and 35c), low side switching elements 40 (40a, 40b, and 40c), low side diodes 45 (45a, 45b, and 45c), and bootstrap units 50 (50a, 50b, and 50c).

The high side switching elements 30 and the low side switching elements 40 switch on and off of the current supplied to the load 210. The high side switching elements 30 and the low side switching elements 40 are voltage-driven switching elements, and are insulated gate bipolar transistors (IGBTs), for example. Alternatively, the switching elements may be power metal-oxide-semiconductor field-effect transistors (MOSFETs) or may be those made of a wide-bandgap semiconductor such as, SiC, GaN, diamond, gallium nitride-based material, gallium oxide-based material, AlN, AlGaN, or ZnO.

Each of the high side switching elements 30 is disposed between a positive terminal P and a corresponding one of the output terminals U, V, and W in the individual phases. Each high side switching element 30 determines whether to connect the positive terminal P and the load 210 based on the gate voltage input to its gate terminal.

Each of the low side switching elements 40 is disposed between a corresponding one of the negative terminals N (U), N (V), and N (W) and a corresponding one of the output terminals U, V, and W in the individual phases. Each low side switching element 40 determines whether to connect a corresponding one of the negative terminals N (U), N (V), and N (W) and the load 210 based on the gate voltage input to its gate terminal.

Each high side diode 35 is a free wheeling diode (FWD) for diverting the load current from the load 210. Each high side diode 35 is connected in parallel to a corresponding one of the high side switching elements 30. Each high side diode 35 may be a diode made of a wide-bandgap semiconductor. When the high side switching elements 30 are MOSFETs, the high side diodes 35 may be realized by parasitic diodes. The high side switching elements 30 and the high side diodes 35 form an upper arm (a high voltage side arm).

Similarly, each of the low side diodes 45 is connected in parallel to a corresponding one of the low side switching elements 40, and is an FWD for diverting the load current from the load 210. Each low side diode 45 may be a diode made of a wide-bandgap semiconductor. When the low side switching elements 40 are MOSFETs, the low side diodes 45 may be realized by parasitic diodes. The low side switching elements 40 and the low side diodes 45 form a lower arm (a low voltage side arm).

Each of the emitter terminals of the upper arm is connected to a corresponding one of the collector terminals of the lower arm. Each of these connection nodes is connected to a corresponding one of the output terminals U, V, and W in the individual phases. The collector terminals of the upper arm are connected to the positive terminal P in the individual phases. The collector terminals of the upper arm in this example are connected to the shared positive terminal P. Each of the emitter terminals of the lower arm is connected to a corresponding one of the negative terminals N (U), N (V), and N (W) in the individual phases. The upper arm and the lower arm in the individual phase form a half-bridge circuit.

The negative terminals N (U), N (V), and N (W) are connected to a terminal 107, which is a shared negative terminal located outside the semiconductor device 100. The power supply 130, which is an output DC power supply, is connected between the positive terminal P and the terminal 107.

The high side drive units 60 are each a high voltage IC (HVIC) that drives a corresponding one of the high side switching elements 30 of the upper arm and that switches on and off of this corresponding one of the high side switching elements 30. The high side drive units 60 each supply a gate voltage based on a gate control input signal from the control unit 110 to the gate terminal of a corresponding one of the high side switching elements 30, and control on and off of this high side switching element 30. The semiconductor device 100 in this example includes three high side drive units 60a, 60b, and 60c in the individual phases.

The high side drive units 60 are each connected to the gate terminal and the emitter terminal of a corresponding one of the high side switching elements 30. Each of the gate terminals of the high side switching elements 30 is connected to a gate output terminal OUT of a corresponding one of the high side drive units 60. Each of the emitter terminals of the high side switching elements 30 is connected to a reference potential terminal Vs of a corresponding one of the high side drive units 60. Each high side drive unit 60 controls electrical connection and disconnection of the collector and the emitter of a corresponding one of the high side switching elements 30 by controlling the voltage between its gate output terminal OUT and its reference potential terminal Vs.

In this way, the high side drive units 60a, 60b, and 60c switch on and off of the high side switching elements 30a, 30b, and 30c in the U phase, V phase, and W phase, respectively. Each high side drive unit 60 is connected to the emitter terminal of a corresponding one of the high side switching elements 30, and has a reference potential terminal Vs, which is set to its reference potential. The reference potential of each high side drive unit 60 is the potential of the emitter of a corresponding one of the high side switching elements 30.

Because the high side drive units 60a, 60b, and 60c have different reference potentials of the operation, the high side drive units 60a, 60b, and 60c are configured as separate drive ICs in the individual phases. Thus, if the separate reference potentials in the individual phases are provided inside an IC, the high side drive units 60a, 60b, and 60c may be integrated in a single IC.

The low side drive unit 20 is a low voltage IC (LVIC) that drives the low side switching elements 40 of the lower arm and that switches on and off of the low side switching elements 40. The low side drive unit 20 supplies a gate voltage based on a gate control input signal from the control unit 110 to the gate terminal of each of the low side switching elements 40, and controls on and off of each of the low side switching elements 40.

The low side drive unit 20 in this example is connected to the three low side switching elements 40a, 40b, and 40c. The low side drive unit 20 has three gate output terminals (U_{OUT}, V_{OUT}, and W_{OUT}), and is connected to each of the gate terminals of the three low side switching elements 40a, 40b, and 40c.

In addition, the low side drive unit 20 is connected to an overcurrent-detection external terminal IS, and receives a sense voltage detected by the current detection resistor 150. When the sense voltage is greater than a threshold, the low side drive unit 20 detects that an overcurrent is flowing through the plurality of low side switching elements 40a, 40b, and 40c. When detecting an overcurrent, the low side drive unit 20 executes a protection operation such as switching the plurality of low side switching elements 40a, 40b, and 40c to off.

The low side drive unit 20 includes a power supply voltage input terminal V_{CC} connected to a low side power supply terminal V_{CCL}, and includes a terminal GND connected to a shared ground terminal COM. The low side drive unit 20 operates by using the voltage between the power supply voltage input terminal V_{CC} and the terminal GND as its power supply voltage.

The emitter terminals of the low side switching elements 40 are connected to the shared ground terminal COM via the current detection resistor 150. That is, the low side drive unit 20 operates by using the potential of the emitter of the low side switching elements 40a, 40b, and 40c as its reference potential. The low side drive unit 20 controls on and off of the low side switching elements 40 by controlling the voltage between the gate output terminals (U_{OUT}, V_{OUT}, and W_{OUT}) and the terminal GND.

The control unit 110 is a microcontroller that controls driving of the semiconductor device 100. The control unit 110 generates gate control input signals to rotate a motor, which is the load 210, with a predetermined number of rotations, and supplies the gate control input signals to the high side drive units 60a, 60b, and 60c and the low side drive unit 20 via drive signal input terminals IN (HU), IN (HV), IN (HW), IN (LU), IN (LV), and IN (LW). For example, the control unit 110 controls the individual gate control input signals based on pulse width modulation (PWM) control.

The load 210 is a three-phase motor having three phases, which are the U phase, the V phase, and the W phase. The semiconductor device 100 may include half-bridge circuits, the number of which matches the number of phases of the motor.

The bootstrap units 50 function as bootstrap diodes (BSD) used for charging the capacitors 140 with a power supply voltage from a high side power supply terminal V_{CCH}.

The bootstrap units 50 are disposed between the high side power supply terminal V_{CCH} and a high side drive external terminal VB. The bootstrap units 50 are also connected between the high side drive external terminal VB and a power supply voltage input terminal V_{CC}.

The capacitors 140 are charged via the bootstrap units 50, and operate the high side drive units 60. The capacitors 140 function as bootstrap capacitors (BSCs) for achieving a rise in voltage such that the obtained voltage will be used as a power supply for the high side drive units 60. The capacitors 140 supply a power supply voltage to the high side drive units 60 in the individual phases via the individual high side drive external terminals VB.

A capacitor 140a is connected between a high side drive external terminal VB (U) and the output terminal U, and is charged by the bootstrap unit 50a. A capacitor 140b is connected between a high side drive external terminal VB (V) and the V terminal, and is charged by the bootstrap unit 50b. A capacitor 140c is connected between a high side drive external terminal VB (W) and the W terminal, and is charged by the bootstrap unit 50c. The capacitors 140a, 140b, and 140c supply a power supply voltage to the high side drive units 60a, 60b, and 60c, respectively.

The current detection resistor 150 is connected between the terminal 107 and a reference potential 105. The current detection resistor 150 is connected outside the semiconductor device 100 such that the current detection resistor 150 is changeable depending on a circuit connected outside the semiconductor device 100. The current detection resistor 150 may be incorporated inside the semiconductor device 100.

In the semiconductor device 100, because each of the high side switching elements 30 of the individual phases turns on at a different timing, two or more of the plurality of low side switching elements 40 do not turn on at the same time. Thus, the low side drive unit 20 is able to detect an overcurrent flowing through the low side switching elements 40 of the three phases by using the single current detection resistor 150.

The low side drive unit 20 has a function of detecting a current flowing through the half-bridge circuit of the individual phase by using the current detection resistor 150 and protecting the module at the occurrence of an overcurrent. The current level signal detected by the current detection resistor 150 is transmitted to the low side drive unit 20 via the overcurrent detection external terminal IS. The low side drive unit 20 executes overcurrent determination, and protects the lower arm by disconnecting the low side switching elements 40 at the occurrence of an overcurrent.

On the other hand, regarding the high side drive units 60, the current level signal detected by the current detection resistor 150 is transmitted to the control unit 110, and the high side drive units 60 protect the upper arm by disconnecting the high side switching elements 30, based on the overcurrent determination executed by the control unit 110 at the occurrence of an overcurrent. The control unit 110 executes the overcurrent determination based on program processing.

FIG. 11 illustrates an example of a circuit configuration of a drive circuit in a semiconductor device. A semiconductor device 100-1 is an equivalent circuit of the inside of the semiconductor device 100 illustrated in FIG. 10.

The semiconductor device 100-1 includes an HVIC 60-1, an LVIC 20-1, a bootstrap unit 50-1, a high side switching element 30-1, a high side diode 35-1, a low side switching element 40-1, and a low side diode 45-1.

The HVIC 60-1 corresponds to the high side drive units 60a, 60b, or 60c, the LVIC 20-1 corresponds to the low side drive unit 20, and the bootstrap unit 50-1 corresponds to the bootstrap unit 50a, 50b, or 50c.

In addition, the high side switching element 30-1 corresponds to the high side switching element 30a, 30b, or 30c, and the high side diode 35-1 corresponds to the high side diode 35a, 35b, or 35c. In addition, the low side switching element 40-1 corresponds to the low side switching element 40a, 40b, or 40c, and the low side diode 45-1 corresponds to the low side diode 45a, 45b, or 45c.

Herein, the LVIC 20-1 (a drive circuit) outputs a gate control signal (a drive control signal) based on a drive signal transmitted from the control unit 110, so as to execute switching control of on and off of the low side switching element 40-1.

The LVIC 20-1 includes a drive control circuit 2a and an overvoltage protection circuit 10-1. The drive control circuit 2a includes Zener diodes ZD21 and ZD22, a resistor R20, a comparator 21, a reference voltage source ref20, a noise filter 22, a delay circuit 23, and a driver 24. The overvoltage protection circuit 10-1 is the overvoltage protection circuit 10a illustrated in FIG. 8 or the overvoltage protection circuit 10b illustrated in FIG. 9.

The low side power supply terminal V_{CCL} is connected to a power supply terminal V_{CC} of the overvoltage protection circuit 10-1 and the cathode of the Zener diode ZD21. The drive signal input terminals IN (LU), IN (LV), and IN (LW) are connected to the anode of the Zener diode ZD21, the cathode of the Zener diode ZD22, one end of the resistor R20, and the non-inverting input terminal (+) of the comparator 21.

The shared ground terminal COM is connected to a ground terminal of the overvoltage protection circuit 10-1, the anode of the Zener diode ZD22, and GND. The other end of the resistor R20 is connected to GND. The positive terminal of the reference voltage source ref20 is connected to the inverting input terminal (−) of the comparator 21, and the negative terminal of the reference voltage source ref20 is connected to GND.

Herein, when any one of the drive signal input terminals IN (LU), IN (LV), and IN (LW) receives a drive signal output for turning on the low side switching element 40-1 from the control unit 110, the drive signal is input to the non-inverting input terminal (+) of the comparator 21.

If the voltage level of the input drive signal is greater than the reference voltage output from the reference voltage source ref20, the comparator 21 outputs an H level signal. The noise filter 22 shapes the output signal from the comparator 21, to remove noise. The delay circuit 23 delays the H level signal, on which noise removal has been executed, by a predetermined time. The driver 24 amplifies the H level signal, which has been delayed by the predetermined time, to the gate threshold voltage level of the low side switching element 40-1, supplies the amplified gate control signal to the gate of the low side switching element 40-1, and turns on the low side switching element 40-1.

The Zener diodes ZD21 and ZD22 connected between the low side power supply terminal V_{CCL} and the shared ground terminal COM are incorporated in the LVIC 20-1 to protect the LVIC 20-1 from input of a surge voltage.

In addition, a hysteresis comparator is used as the comparator 21. The hysteresis comparator is a circuit in which hysteresis setting has been made such that the output level will not be switched frequently even when the circuit is affected by a short-time level fluctuation. By using a hysteresis comparator, the comparator 21 outputs a stable H level (or L level) signal.

In the LVIC 20-1, the overvoltage protection circuit 10-1 is disposed between the low side power supply terminal V_{CCL} and the shared ground terminal COM. With this configuration as described above, even when an overvoltage such as ESD is applied to the low side power supply terminal V_{CCL} of the LVIC 20-1, because the overvoltage protection circuit 10-1 executes stepwise overvoltage protection based on the magnitude of the overvoltage, it is possible to prevent deterioration in overvoltage protection function while preventing destruction of the circuit elements in the LVIC 20-1, and to accurately and reliably realize overvoltage protection. In FIG. 11, although the LVIC includes the overvoltage protection function, the embodiments are not limited to this example. The HVIC may be configured to include the overvoltage protection function.

While embodiments have thus been described as examples, any one of the individual elements in the embodiments may be replaced by a different element having an equivalent function. In addition, other elements or steps may be added. Two or more elements (features) in the above-described embodiments may be combined with each other.

In one aspect, it is possible to execute stepwise overvoltage protection and prevent destruction of circuit elements.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An overvoltage protection circuit, comprising:
a power supply terminal having a voltage applied thereto;
a ground terminal;
an overvoltage detection circuit configured to detect whether the voltage applied to the power supply terminal is in an overvoltage state;
a resistance value selection circuit configured to select a resistance value from a plurality of resistance values, depending on the overvoltage state; and
a clamp circuit which includes
a resistor unit providing the plurality of resistance values, and
a transistor configured to be turned on by a drive current thereof that flows based on the selected resistance value, to thereby form a current path between the power supply terminal and the ground terminal to draw a current from the power supply terminal, so as to clamp the voltage.

2. The overvoltage protection circuit according to claim 1, wherein
the overvoltage state detected by the overvoltage detection circuit is one among a plurality of overvoltage states, and is detected based on a magnitude of the voltage, and
the one resistance value selected by the resistance value selection circuit has a greater value as the voltage increases.

3. The overvoltage protection circuit according to claim 2, wherein the overvoltage state detected by the overvoltage detection circuit is
a first overvoltage state when the voltage is a first voltage value or greater, and
a second overvoltage state when the voltage is a second voltage value or greater, the second voltage value being higher than the first voltage value.

4. The overvoltage protection circuit according to claim 3, wherein
the resistor unit includes a polyimide resistor, and has a first end and a second end;
the clamp circuit further includes a Zener diode connected in reverse series to the first end of the resistor unit; and
the resistance value selection circuit is configured to
allow, upon detecting the first overvoltage state, a current to flow from the power supply terminal to a first point of the resistor unit that is located between the first end and the second end of the resistor unit and is connected to a base of the transistor, and select a first resistance value that is formed between the first point and the second end of the resistor unit, and
allow, upon detecting the second overvoltage state, a current to flow from the power supply terminal to the first end of the resistor unit, and select a second resistance value that is formed between the first end and the second end of the resistor unit, the second resistance value being greater than the first resistance value.

5. The overvoltage protection circuit according to claim 4,
wherein a collector of the transistor is connected to the power supply terminal, and an emitter of the transistor is connected to the ground terminal,
wherein in response to flowing of a current through the Zener diode in the first overvoltage state, the transistor is turned on by a first drive current that flows through the resistor unit having the first resistance value, to thereby draw a first current from the power supply terminal, and
wherein in response to flowing of a current through the Zener diode in the second overvoltage state, the transistor is turned on by a second drive current that flows through the resistor unit having the second resistance value to thereby draw a second current from the power supply terminal, the second drive current being less than the first drive current, and a current amount of the second current being less than a current amount of the first current.

6. The overvoltage protection circuit according to claim 5,
wherein the overvoltage detection circuit includes:
a first comparator having an inverting input terminal, a non-inverting input terminal and an output terminal,
a first voltage divider resistor,
a second voltage divider resistor,
a first reference voltage source outputting a first reference voltage,
a second comparator having an inverting input terminal, a non-inverting input terminal and an output terminal,
a third voltage divider resistor,
a fourth voltage divider resistor,
a second reference voltage source outputting a second reference voltage,
an AND element having a first input terminal, a second input terminal, and an output terminal, and
an inverter element having an input terminal and an output terminal;
wherein the resistance value selection circuit includes:
a first resistance value selection circuit including a first transistor and a first base resistor, and
a second resistance value selection circuit including a second transistor and a second base resistor;
wherein a first voltage obtained by dividing the voltage with the first voltage divider resistor and the second voltage divider resistor is input to the non-inverting input terminal of the first comparator, and the first reference voltage output from the first reference voltage source is input to the inverting input terminal of the first comparator;
wherein a second voltage obtained by dividing the voltage with the third voltage divider resistor and the fourth voltage divider resistor is input to the non-inverting input terminal of the second comparator, and the second reference voltage output from the second reference voltage source is input to the inverting input terminal of the second comparator;
wherein a collector of the first transistor and a collector of the second transistor are connected to the power supply terminal;
wherein the output terminal of the first comparator is connected to the first input terminal of the AND element, and the output terminal of the second comparator is connected to the input terminal of the inverter element and a base of the second transistor via the second base resistor;
wherein the output terminal of the inverter element is connected to the second input terminal of the AND element, and the output terminal of the AND element is connected to a base of the first transistor via the first base resistor;
wherein an emitter of the first transistor is connected to the first point of the resistor unit, and an emitter of the second transistor is connected to the first end of the resistor unit and a cathode of the Zener diode; and
wherein the second end of the resistor unit is connected to the base of the transistor, the emitter of the transistor is connected to an anode of the Zener diode and the ground terminal, and a pull-down resistor is connected between the base of the transistor and the ground terminal.

7. The overvoltage protection circuit according to claim 3,
wherein the resistor unit includes a first resistor having a first end a second end, and a second resistor having a first end a second end,
wherein the clamp circuit further includes a Zener diode connected in reverse series to the first end of the first resistor and the first end of the second resistor,
wherein upon detecting the first overvoltage state, the resistance value selection circuit selects a first resistance value, which is a value of the first resistor, and
wherein upon detecting the second overvoltage state, the resistance value selection circuit selects a second resistance value, which is a sum of the first resistance value and a resistance value of the second resistor.

8. The overvoltage protection circuit according to claim 7,
wherein a collector of the transistor is connected to the power supply terminal, and an emitter of the transistor is connected to the ground terminal,
wherein in response to flowing of a current through the Zener diode in the first overvoltage state, the transistor is turned on by a first drive current that flows through the first resistor having the first resistance value, to thereby draw a first current from the power supply terminal, and
wherein in response to flowing of a current through the Zener diode in the second overvoltage state, the transistor is turned on by a second drive current that flows through the first resistor and the second resistor connected in series, to thereby draw a second current from the power supply terminal, the second drive current being less than the first drive current, and a current amount of the second current being less than a current amount of the first current.

9. The overvoltage protection circuit according to claim 8,
wherein the overvoltage detection circuit includes:
a first comparator having an inverting input terminal, a non-inverting input terminal and an output terminal,
a first voltage divider resistor,
a second voltage divider resistor,
a first reference voltage source outputting a first reference voltage,
a second comparator having an inverting input terminal, a non-inverting input terminal and an output terminal,
a third voltage divider resistor,
a fourth voltage divider resistor,
a second reference voltage source outputting a second reference voltage,
an AND element having a first input terminal, a second input terminal, and an output terminal, and
an inverter element having an input terminal and an output terminal;
wherein the resistance value selection circuit includes:
a first resistance value selection circuit including a first transistor and a first base resistor, and
a second resistance value selection circuit including a second transistor and a second base resistor;
wherein a first voltage obtained by dividing the voltage with the first voltage divider resistor and the second voltage divider resistor is input to the non-inverting input terminal of the first comparator, and the first reference voltage output from the first reference voltage source is input to the inverting input terminal of the first comparator;
wherein a second voltage obtained by dividing the voltage with the third voltage divider resistor and the fourth voltage divider resistor is input to the non-inverting input terminal of the second comparator, and the second reference voltage output from the second reference voltage source is input to the inverting input terminal of the second comparator,
wherein a collector of the first transistor and a collector of the second transistor are connected to the power supply terminal;
wherein the output terminal of the first comparator is connected to the first input terminal of the AND element, and the output terminal of the second comparator is connected to the input terminal of the inverter element and a base of the second transistor via the second base resistor;
wherein the output terminal of the inverter element is connected to the second input terminal of the AND element, and the output terminal of the AND element is connected to a base of the first transistor via the first base resistor;
wherein an emitter of the first transistor is connected to the first end of the first resistor, the first end of the second resistor, and a cathode of the Zener diode, an emitter of the second transistor is connected to the second end of the second resistor, and the second end of the first resistor is connected to a base of the transistor, and
wherein the emitter of the transistor is connected to an anode of the Zener diode and the ground terminal, and a pull-down resistor is connected between the base of the transistor and the ground terminal.

10. A semiconductor device, comprising:
a switching element configured to execute switching based on a drive control signal, for operating a load; and
a drive circuit including:
a drive control circuit that outputs the drive control signal based on a drive signal, and
a drive circuit that includes an overvoltage protection circuit, wherein
the overvoltage protection circuit includes
a power supply terminal having a voltage applied thereto;
a ground terminal;
an overvoltage detection circuit configured to detect whether the voltage applied to the power supply terminal is in an overvoltage state,
a resistance value selection circuit configured to select a resistance value from a plurality of resistance values, depending on the overvoltage state, and
a clamp circuit which includes:
a resistor unit providing the plurality of resistance values, and
a transistor configured to be turned on by a drive current thereof that flows based on the selected resistance value, to thereby form a current path between the power supply terminal and the ground terminal to draw a current from the power supply terminal,
so as to clamp the voltage.

11. The semiconductor device according to claim 10, wherein
the overvoltage state detected by the overvoltage detection circuit is one among a plurality of overvoltage states and is detected based on a magnitude of the voltage, and
the one resistance value selected by the resistance value selection circuit has a greater value as the voltage increases.

12. The semiconductor device according to claim 11, wherein the overvoltage state detected by the overvoltage detection circuit is
a first overvoltage state when the voltage is a first voltage value or greater, and
a second overvoltage state when the voltage is the second voltage value or greater, the second voltage value being higher than the first voltage value.

13. The semiconductor device according to claim 12, wherein
the resistor unit includes a polyimide resistor, and has a first end and a second end;
the clamp circuit further includes a Zener diode connected in reverse series to the first end of the resistor unit; and
the resistance value selection circuit is configured to
allow, upon detecting the first overvoltage state, a current to flow from the power supply terminal to a first point of the resistor unit that is located between the first end and the second end of the resistor unit and is connected to a base of the transistor, and select a first resistance value that is formed between the first point and the second end of the resistor unit, and
allow, upon detecting the second overvoltage state, a current to flow from the power supply terminal to the first end of the resistor unit, and select a second resistance value that is formed between the first end and the second end of the resistor unit, the second resistance value being greater than the first resistance value.

14. The semiconductor device according to claim 13,
wherein a collector of the transistor is connected to the power supply terminal, and an emitter of the transistor is connected to the ground terminal,
wherein in response to flowing of a current through the Zener diode in the first overvoltage state, the transistor is turned on by a first drive current that flows through the resistor unit having the first resistance value, to thereby draws a first current from the power supply terminal, and
wherein in response to flowing of a current through the Zener diode in the second overvoltage state, the transistor is turned on by a second drive current that flows through the resistor unit having the second resistance value, to thereby draw a second current from the power supply terminal, the second drive current being less than the first drive current, and a current amount of the second current being less than a current amount of the first current.

15. The semiconductor device according to claim 14,
wherein the overvoltage detection circuit includes:
a first comparator having an inverting input terminal, a non-inverting input terminal and an output terminal,
a first voltage divider resistor,
a second voltage divider resistor,
a first reference voltage source outputting a first reference voltage,
a second comparator having an inverting input terminal, a non-inverting input terminal and an output terminal,
a third voltage divider resistor,
a fourth voltage divider resistor,
a second reference voltage source outputting a second reference voltage,
an AND element having a first input terminal, a second input terminal, and an output terminal, and
an inverter element having an input terminal and an output terminal;
wherein the resistance value selection circuit includes:
a first resistance value selection circuit including a first transistor and a first base resistor, and
a second resistance value selection circuit including a second transistor and a second base resistor;
wherein a first voltage obtained by dividing the voltage with the first voltage divider resistor and the second voltage divider resistor is input to the non-inverting input terminal of the first comparator, and the first reference voltage output from the first reference voltage source is input to the inverting input terminal of the first comparator;
wherein a second voltage obtained by dividing the voltage with the third voltage divider resistor and the fourth voltage divider resistor is input to the non-inverting input terminal of the second comparator, and the second reference voltage output from the second reference voltage source is input to the inverting input terminal of the second comparator;
wherein a collector of the first transistor and a collector of the second transistor are connected to the power supply terminal;
wherein the output terminal of the first comparator is connected to the first input terminal of the AND element, and the output terminal of the second comparator is connected to the input terminal of the inverter element and a base of the second transistor via the second base resistor;
wherein the output terminal of the inverter element is connected to the second input terminal of the AND element, and the output terminal of the AND element is connected to a base of the first transistor via the first base resistor;
wherein an emitter of the first transistor is connected to the first point of the resistor unit, and an emitter of the second transistor is connected to the first end of the resistor unit and a cathode of the Zener diode; and
wherein the second end of the resistor unit is connected to the base of the transistor, the emitter of the transistor is connected to an anode of the Zener diode and the ground terminal, and a pull-down resistor is connected between the base of the transistor and the ground terminal.

16. The semiconductor device according to claim 12,
wherein the resistor unit includes a first resistor having a first end a second end, and a second resistor having a first end a second end,
wherein the clamp circuit further includes a Zener diode connected in reverse series to the first end of the first resistor and the first end of the second resistor,
wherein upon detecting the first overvoltage state, the resistance value selection circuit selects a first resistance value, which is a value of the first resistor, and
wherein upon detecting the second overvoltage state, the resistance value selection circuit selects a second resistance value, which is a sum of the first resistance value and a resistance value of the second resistor.

17. The semiconductor device according to claim 16,
wherein a collector of the transistor is connected to the power supply terminal, and an emitter of the transistor is connected to the ground terminal,
wherein in response to flowing of a current through the Zener diode in the first overvoltage state, the transistor is turned on by a first drive current that flows through the first resistor having the first resistance value, to thereby draw a first current from the power supply terminal, and
wherein in response to flowing of a current through the Zener diode in the second overvoltage state, the transistor is turned on by a second drive current that flows through the first resistor and the second resistor connected in series, to thereby draw a second current from the power supply terminal, the second drive current being less than the first drive current, and a current amount of the second current being less than a current amount of the first current.

18. The semiconductor device according to claim 17,
wherein the overvoltage detection circuit includes:
a first comparator having an inverting input terminal, a non-inverting input terminal and an output terminal,
a first voltage divider resistor,
a second voltage divider resistor,
a first reference voltage source outputting a first reference voltage,
a second comparator having an inverting input terminal, a non-inverting input terminal and an output terminal,
a third voltage divider resistor,
a fourth voltage divider resistor,
a second reference voltage source outputting a second reference voltage,
an AND element having a first input terminal, a second input terminal, and an output terminal, and
an inverter element having an input terminal and an output terminal;
wherein the resistance value selection circuit includes:
a first resistance value selection circuit including a first transistor and a first base resistor, and
a second resistance value selection circuit including a second transistor and a second base resistor,
wherein a first voltage obtained by dividing the voltage with the first voltage divider resistor and the second voltage divider resistor is input to the non-inverting input terminal of the first comparator, and the first reference voltage output from the first reference voltage source is input to the inverting input terminal of the first comparator;
wherein a second voltage obtained by dividing the voltage with the third voltage divider resistor and the fourth voltage divider resistor is input to the non-inverting input terminal of the second comparator, and the second reference voltage output from the second reference voltage source is input to the inverting input terminal of the second comparator;
wherein a collector of the first transistor and a collector of the second transistor are connected to the power supply terminal;
wherein the output terminal of the first comparator is connected to the first input terminal of the AND element, and the output terminal of the second comparator is connected to the input terminal of the inverter element and a base of the second transistor via the second base resistor;
wherein the output terminal of the inverter element is connected to the second input terminal of the AND element, and the output terminal of the AND element is connected to a base of the first transistor via the first base resistor;
wherein an emitter of the first transistor is connected to the first end of the first resistor, the first end of the second resistor, and a cathode of the Zener diode, an emitter of the second transistor is connected to the second end of the second resistor, and the second end of the first resistor is connected to a base of the transistor; and
wherein the emitter of the transistor is connected to an anode of the Zener diode and the ground terminal, and a pull-down resistor is connected between the base of the transistor and the ground terminal.
